(19) United States
(12) Patent Application Publication
(10) Pub. No.: US 2011/0242768 A1
(43) Pub. Date: Oct. 6, 2011

(54) POWER SUPPLY AND HANDLE STRUCTURE THEREOF

(75) Inventor: Shao-Feng Lu, Taoyuan County (TW)

(73) Assignees: FSP TECHNOLOGY INC., Taoyuan County (TW); 3Y POWER TECHNOLOGY (TAIWAN), INC., Taoyuan County (TW)

(21) Appl. No.: 12/752,124

(22) Filed: Apr. 1, 2010

(51) Int. Cl. H05K 7/14; B65D 25/28

(52) U.S. Cl. 361/726; 16/110.1

(57) ABSTRACT

A handle structure includes a holding portion, a first inner-thread structure and a second inner-thread structure. The holding portion has a first fixing pillar, a second fixing pillar and a force-applying rod connected between the first fixing pillar and the second fixing pillar parallel to the first fixing pillar. The first inner-thread structure is inlaid in the first end of the first fixing pillar. The first fixing pillar has a first height perpendicular to the faceplate, and the height of the first inner-thread structure perpendicular to the faceplate is greater than the half of the first height. The second inner-thread structure is inlaid in the second end of the second fixing pillar. The second fixing pillar has a second height perpendicular to the faceplate, and the height of the second inner-thread structure perpendicular to the faceplate is greater than the half of the second height.

### BACKGROUND OF THE INVENTION

1. Field of the Invention

The present invention generally relates to a power supply, and more particularly, to a power supply and the handle structure thereof.

2. Description of Related Art

Usually, an electrical device such as a industrial computer host or a server mostly adopts a power supply conformable to the system operation demand so as to convert an AC power into a DC power with capability of meeting the power requirement for the system operation. In the prior art, a common power supply has different output power specifications for user selection, and in addition, has a body compatible with the general electrical device. The body of the power supply should includes disposing thread holes to conform the requirement of the electrical device for assembling and disassembling. The body even employs an electrical connection terminal so that a drawer power supply can link the electrical device directly by plugging in.

In terms of application practices however, when the user holds the handle of the power supply's body and applies a side force thereon, due to the small outer diameter of the handle, the handle easily gets fracture by the side bending. Moreover, due to the smaller faceplate of the body so as to hardly accommodate a larger handle and the safety standard limitation so as to hardly employ a metal handle with larger strength, the conventional insulation handle is allowed to use general small screws to be fixed on the faceplate and the conventional handle is obviously strength-insufficient. Under the situation, the handle easily gets fracture by a moment of a side force at the joint place with weaker structure strength. Therefore, it is very important to solve the insufficient strength problem with a conventional handle.

### SUMMARY OF THE INVENTION

Accordingly, the present invention is directed to a power supply and the handle structure thereof to increase the structure strength of the handle.

The present invention provides a handle structure assembled on a faceplate, and the handle structure includes a holding portion, a first inner-thread structure and a second inner-thread structure. The holding portion has a first fixing pillar, a second fixing pillar and a force-applying rod connected between the first fixing pillar and the second fixing pillar parallel to the first fixing pillar. The first inner-thread structure is inlaid in the first end of the first fixing pillar. The first fixing pillar has a first height perpendicular to the faceplate, and the height of the first inner-thread structure perpendicular to the faceplate is greater than the half of the first height. The second inner-thread structure is inlaid in the second end of the second fixing pillar. The second fixing pillar has a second height perpendicular to the faceplate, and the height of the second inner-thread structure perpendicular to the faceplate is greater than the half of the second height.

The present invention provides a power supply assembled in an electrical device and includes a casing, an elastic fastening strip and a handle structure. The elastic fastening strip is disposed at the side of the casing and protruded out of the faceplate. The handle structure is assembled on the faceplate and includes a holding portion, a first inner-thread structure and a second inner-thread structure. The holding portion has a first fixing pillar, a second fixing pillar and a force-applying rod connected between the first fixing pillar and the second fixing pillar parallel to the first fixing pillar. The first inner-thread structure is inlaid in the first end of the first fixing pillar. The first fixing pillar has a first height perpendicular to the faceplate, and the height of the first inner-thread structure perpendicular to the faceplate is greater than the half of the first height. The second inner-thread structure is inlaid in the second end of the second fixing pillar. The second fixing pillar has a second height perpendicular to the faceplate, and the height of the second inner-thread structure perpendicular to the faceplate is greater than the half of the second height.

In an embodiment of the present invention, the above-mentioned first inner-thread structure has a first thread hole for accommodating a first bolt, and the first bolt goes through the faceplate to be fastened in the first thread hole.

In an embodiment of the present invention, the above-mentioned first bolt has a first length, which is substantially equal to the height of the first inner-thread structure perpendicular to the faceplate.

In an embodiment of the present invention, an end of the above-mentioned first inner-thread structure far away from the faceplate is a conic body structure having a first outer diameter and a slanted surface and the slanted surface is tilted towards the first thread hole so as to form a second outer diameter smaller than the first outer diameter.

In an embodiment of the present invention, the above-mentioned first fixing pillar has an enhancing structure formed in the conic body structure.

In an embodiment of the present invention, the above-mentioned second inner-thread structure has a second thread hole for accommodating a second bolt, and the second bolt goes through the faceplate to be fastened in the second thread hole.

In an embodiment of the present invention, the above-mentioned second bolt has a second length, which is substantially equal to the height of the second inner-thread structure perpendicular to the faceplate.

In an embodiment of the present invention, an end of the above-mentioned second inner-thread structure far away from the faceplate is a conic body structure having a first outer diameter and a slanted surface and the slanted surface is tilted towards the second thread hole so as to form a second outer diameter smaller than the first outer diameter.

In an embodiment of the present invention, the above-mentioned second fixing pillar has an enhancing structure formed in the conic body structure.

In an embodiment of the present invention, the above-mentioned first fixing pillar is formed by injecting plastic and encloses the first inner-thread structure.

In an embodiment of the present invention, the above-mentioned second fixing pillar is formed by injecting plastic and encloses the second inner-thread structure.

In an embodiment of the present invention, the above-mentioned first fixing pillar, second fixing pillar and force-applying rod together form a [symbol] -shape structure.

Based on the depiction above, the present invention provides a handle structure with higher strength so that the handle is not easily to get fracture by the moment of a side force at the joint place with weaker structure strength. In this way, the insufficient strength problem of the conventional handle structure is solved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram of a handle structure according to an embodiment of the present invention.

FIG. 2 is a sectional diagram of the inner-thread structure of the handle structure in FIG. 1.

FIG. 3A is a sectional diagram of the inner-thread structure of a handle structure according to another embodiment of the present invention.

FIG. 3B is a sectional diagram of the inner-thread structure in FIG. 3A across line A-A.

FIG. 4 is a diagram of a power supply according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

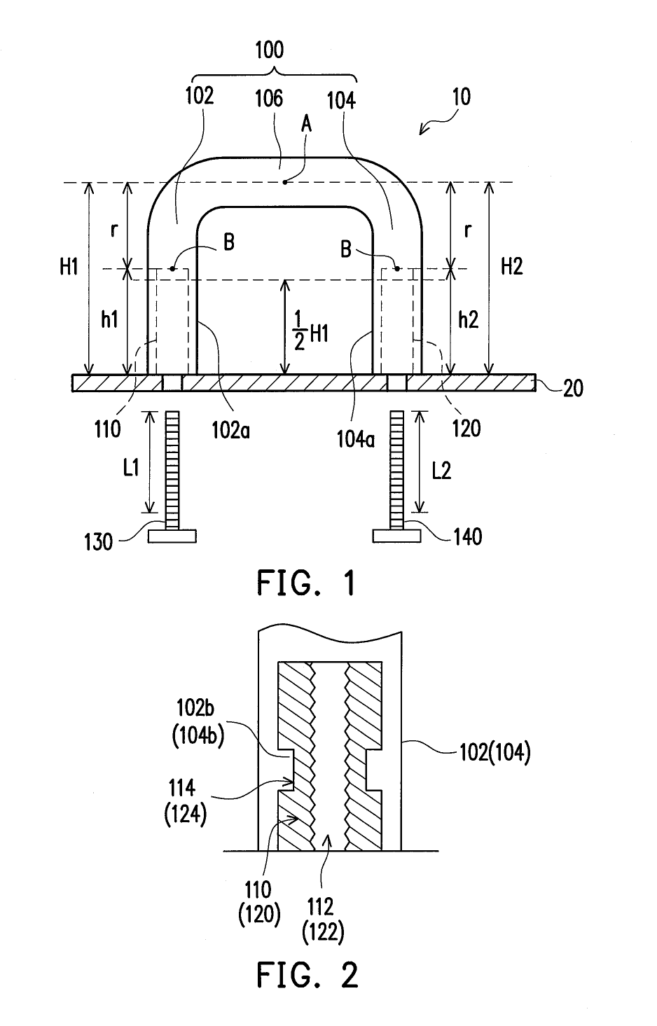

FIG. 1 is a diagram of a handle structure according to an embodiment of the present invention and FIG. 2 is a sectional diagram of the inner-thread structure of the handle structure in FIG. 1. Referring to FIGS. 1 and 2, a handle structure 10 is assembled on a faceplate 20 and the handle structure 10 includes a holding portion 100, a first inner-thread structure 110 and a second inner-thread structure 120. The holding portion 100 has a first fixing pillar 102, a second fixing pillar 104 and a force-applying rod 106 connected between the first fixing pillar 102 and the second fixing pillar 104 parallel to the first fixing pillar 102. The first inner-thread structure 110 is inlaid in the first end 102a of the first fixing pillar 102. The first fixing pillar 102 has a first height H1 perpendicular to the faceplate 20, and the height h1 of the first inner-thread structure 110 perpendicular to the faceplate 20 is greater than the half of the first height H1, expressed by H1>h1>H1/2. In addition, the second inner-thread structure 120 is inlaid in the second end 104a of the second fixing pillar 104. The second fixing pillar 104 has a second height H2 perpendicular to the faceplate 20, and the height h2 of the second inner-thread structure 120 perpendicular to the faceplate 20 is greater than the half of the second height H2, expressed by H2>h2>H2/2

Assuming the first fixing pillar 102 and the second fixing pillar 104 have the same height, and the heights of the first inner-thread structure 110 and the second inner-thread structure 120 perpendicular to the faceplate 20 are the same as well, then, the ends of the first inner-thread structure 110 and the second inner-thread structure 120 would be beyond the middle lines of the first fixing pillar 102 and the second fixing pillar 104, i.e., beyond the halves of the first height and the second height. As a result, the strength of the handle structure 10 withstanding deformation is relatively enhanced. Meanwhile, the force-arm length r between the force-applying point A on the force-applying rod 106 and the force-accepting point B at a joint place with a weaker strength is relatively shortened so as to make r at least less than a half of any of the two fixing pillars, and thereby, the moment amount (product of the force by the force-arm length) is reduced.

Referring to FIG. 2, the first inner-thread structure 110 has a first thread hole 112 for accommodating the first bolt 130, wherein the first bolt 130 goes through the faceplate 20 to be fastened in the first thread hole 112. In the embodiment, the first bolt 130 has a first length L1, which is substantially equal to the height h1 of the first inner-thread structure 110 perpendicular to the faceplate 20. Similarly, the second inner-thread structure 120 has a second thread hole 122 for accommodating the second bolt 140, wherein the second bolt 140 goes through the faceplate 20 to be fastened in the second thread hole 122. In the embodiment, the second bolt 140 has a second length L2, which is substantially equal to the height h2 of the second inner-thread structure 120 perpendicular to the faceplate 20.

In the embodiment, the first fixing pillar 102 is formed, for example, by injecting plastic and encloses the first inner-thread structure 110. At the outside of the first inner-thread structure 110, a groove 114 is disposed and the first fixing pillar 102 has an inlay portion 102b protruded from the first fixing pillar 102 and located corresponding to the groove 114, so that the first inner-thread structure 110 and the first fixing pillar 102 are fastened by each other. The first inner-thread structure 110 can have a dumbbell-shape, i.e. a cylinder shape having two ends respectively with a dimension greater than the dimension of the middle portion of the cylinder. The first fixing pillar 102 has thermal isolation effect so as to conform the safety standard.

Similarly, the second fixing pillar 104 is formed, for example, by injecting plastic and encloses the second inner-thread structure 120. At the outside of the second inner-thread structure 120, a groove 124 is disposed and the second fixing pillar 104 has an inlay portion 104b protruded from the second fixing pillar 104 and located corresponding to the groove 124, so that the second inner-thread structure 120 and the second fixing pillar 104 are knocked by each other. The second inner-thread structure 120 can have a dumbbell-shape, i.e. a cylinder shape having two ends respectively with a dimension greater than the dimension of the middle portion of the cylinder. The second fixing pillar 104 has thermal isolation effect so as to conform the safety standard.

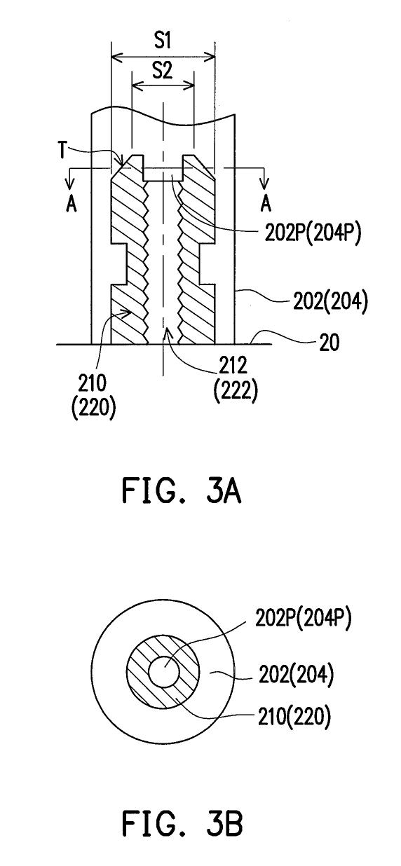

FIG. 3A is a sectional diagram of the inner-thread structure of a handle structure according to another embodiment of the present invention and FIG. 3B is a sectional diagram of the inner-thread structure in FIG. 3A across line A-A. Referring to FIGS. 3A and 3B, there are a first inner-thread structure 210 and a second inner-thread structure 220, wherein an end of each of the first inner-thread structure 210 and the second inner-thread structure 220 is far away from the faceplate 20 and the end is, for example, a conic body structure which has a first outer diameter S1 and a slanted surface T (i.e. chamfer). The slanted surface T is tilted towards the inner thread hole to form a second outer diameter S2 less than the first outer diameter S1. The second outer diameter S2 can be greater than or equal to the diameter of the thread hole 212 of the first inner-thread structure 210 and the diameter of the thread hole 222 of the second inner-thread structure 220, which the present invention is not limited to. Besides, when the first fixing pillar 202 is formed by injecting plastic and encloses the first inner-thread structure 210, the first fixing pillar 202 is also formed in the conic body structure so as to form an enhancing structure 202p. As shown in FIG. 3B, the enhancing structure 202p (i.e. cylindrical countersunk head) enables the first inner-thread structure 210 having a larger section area, which is advantageous in preventing a joint place with weaker structure strength from being fractured when a side force is applied thereon. Similarly, when the second fixing pillar 204 is formed by injecting plastic and encloses the second inner-thread structure 220, the second fixing pillar 204 is also formed in the conic body structure so as to form an enhancing structure 204p to prevent a fracture.

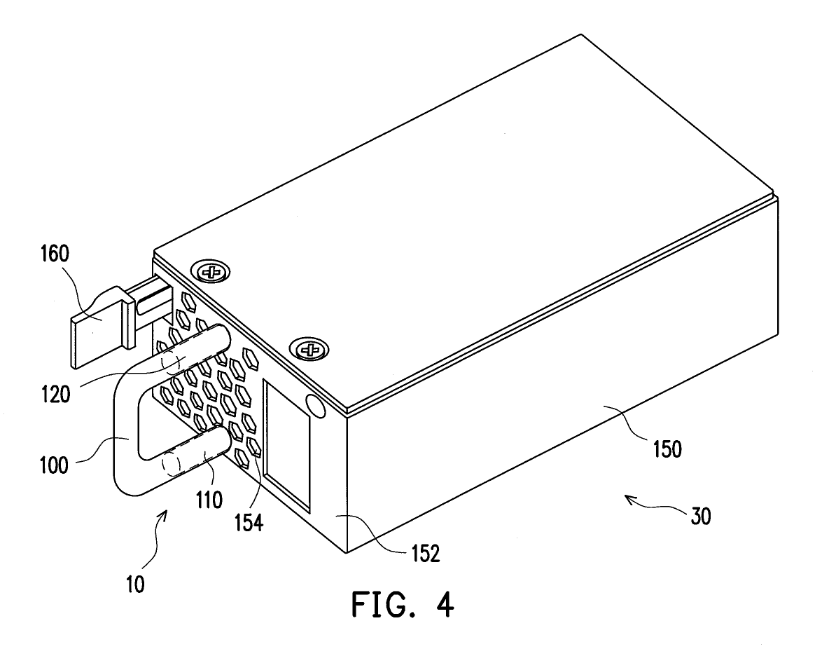

FIG. 4 is a diagram of a power supply according to an embodiment of the present invention. A power supply 30 can be assembled in an electrical device to convert an AC power (or a DC power) into a DC power required by a system operation. In order to make the casing 150 of the power supply 30 in plug/unplug way assembled in the electrical device, a handle structure 10 and an elastic fastening strip 160 are employed and disposed on the casing 150, wherein the elastic fastening strip 160 is disposed at the side of the casing 150 and protruded out of the faceplate 152 of the power supply, while the handle structure 10 is assembled on the faceplate 152. The faceplate 152 has a plurality of mesh holes 154 for heat dissipation thereon. In a practical operation, a user holds the handle structure 10 and presses down the elastic fastening strip 160 with s thumb of the user so as to move the elastic fastening strip 160 inwards to release the fastening action of the elastic fastening strip 160. After that, the user applies a forwarding force on the handle structure 10 and then pulls the casing 150 out of the electrical device. Similarly, the user can plug the casing 150 into the electrical device and make the elastic fastening strip 160 fastening and fixing the casing 150.

Continuing to FIGS. 1 and 4, the holding portion 100 of the handle structure 10 includes a first fixing pillar 102, a second fixing pillar 104 and a force-applying rod 106 to form a [symbol] -shape structure. In this way, the user can easily apply a side force to release the fastening action of the elastic fastening strip 160, followed by applying a forwarding force to pull out the casing 150. It should be noted that the first inner-thread structure 110 and the second inner-thread structure 120 are respectively located at both sides of the [symbol] -shape structure and are respectively inlaid in the first fixing pillar 102 and the second fixing pillar 104. The above-mentioned design is like that there are two metal bushes with larger strength added in the handle, which can withstand the moment produced by the side force. In other words, when the first inner-thread structure 110 or the second inner-thread structure 120 has a longer length, the force-arm length r between the force-applying point A on the force-applying rod 106 and the force-accepting point B at the joint place with a weaker structure strength is relatively shortened. In comparison with the conventional design where the force-arm length between the force-applying point and the force-accepting point on a conventional handle structure is roughly equal to the length of the fixing pillar, the present invention can largely reduce the moment produced by a side force.

In summary, the present invention features to increase the strength of the handle structure, so that the handle structure is unlikely fractured by a moment produced by a side force at the joint place with a weaker structure strength thereof. Therefore, the present invention can solve the conventional problem of the insufficient strength of the handle structure.

It will be apparent to those skilled in the art that the descriptions above are several preferred embodiments of the present invention only, which does not limit the implementing range of the present invention. Various modifications and variations can be made to the structure of the present invention without departing from the scope or spirit of the invention.

1. A handle structure, assembled on a faceplate and comprising:
a holding portion, having a first fixing pillar, a second fixing pillar and a force-applying rod connected between the first fixing pillar and the second fixing pillar parallel to the first fixing pillar, wherein the first fixing pillar has a first length perpendicular to the faceplate, and the second fixing pillar has a second length perpendicular to the faceplate;
a first inner-thread structure, inlaid in a first end of the first fixing pillar, wherein the first inner-thread structure has a third length perpendicular to the faceplate and greater than a half of the first length; and
a second inner-thread structure, inlaid in a second end of the second fixing pillar, wherein the second inner-thread structure has a fourth length perpendicular to the faceplate and greater than a half of the second length.

2. The handle structure as claimed in claim 1, wherein the first inner-thread structure has a first thread hole for accommodating a first bolt, and the first bolt goes through the faceplate to be fastened in the first thread hole.

3. The handle structure as claimed in claim 2, wherein the first bolt has a fifth length, substantially equal to the third length of the first inner-thread structure perpendicular to the faceplate.

4. The handle structure as claimed in claim 2, wherein an end of the first inner-thread structure far away from the faceplate is a conic body structure having a first outer diameter and a slanted surface and the slanted surface is tilted towards the first thread hole so as to form a second outer diameter smaller than the first outer diameter.

5. The handle structure as claimed in claim 4, wherein the first fixing pillar has an enhancing structure formed in the conic body structure.

6. The handle structure as claimed in claim 1, wherein the second inner-thread structure has a second thread hole for accommodating a second bolt, and the second bolt goes through the faceplate to be fastened in the second thread hole.

7. The handle structure as claimed in claim 6, wherein the second bolt has a sixth length, substantially equal to the fourth length of the second inner-thread structure perpendicular to the faceplate.

8. The handle structure as claimed in claim 6, wherein an end of the second inner-thread structure far away from the faceplate is a conic body structure having a first outer diameter and a slanted surface and the slanted surface is tilted towards the second thread hole so as to form a second outer diameter smaller than the first outer diameter.

9. The handle structure as claimed in claim 8, wherein the second fixing pillar has an enhancing structure formed in the conic body structure.

10. The handle structure as claimed in claim 1, wherein the first fixing pillar is formed by injecting plastic and encloses the first inner-thread structure.

11. The handle structure as claimed in claim 1, wherein the second fixing pillar is formed by injecting plastic and encloses the second inner-thread structure.

12. The handle structure as claimed in claim 1, wherein the first fixing pillar, second fixing pillar and force-applying rod together form an U-shape structure.

13. A power supply, assembled in an electrical device and comprising:
a casing, having a faceplate;
an elastic fastening strip, disposed at a side of the casing and protruded out of the faceplate; and
a handle structure, assembled on the faceplate and comprising:
a holding portion, having a first fixing pillar, a second fixing pillar and a force-applying rod connected between the first fixing pillar and the second fixing pillar parallel to the first fixing pillar, wherein the first fixing pillar has a first length perpendicular to the faceplate, and the second fixing pillar has a second length perpendicular to the faceplate;
a first inner-thread structure, inlaid in a first end of the first fixing pillar, wherein the first inner-thread structure has a third length perpendicular to the faceplate and greater than a half of the first length; and
a second inner-thread structure, inlaid in a second end of the second fixing pillar, wherein the second inner-thread structure has a fourth length perpendicular to the faceplate and greater than a half of the second length.

14. The power supply as claimed in claim 13, wherein the first inner-thread structure has a first thread hole for accommodating a first bolt, and the first bolt goes through the faceplate to be fastened in the first thread hole.

15. The power supply as claimed in claim 14, wherein the first bolt has a fifth length, substantially equal to the third length of the first inner-thread structure perpendicular to the faceplate.

16. The power supply as claimed in claim 13, wherein the second inner-thread structure has a second thread hole for accommodating a second bolt, and the second bolt goes through the faceplate to be fastened in the second thread hole.

17. The power supply as claimed in claim 16, wherein the second bolt has a sixth length, substantially equal to the fourth length of the second inner-thread structure perpendicular to the faceplate.

18. The power supply as claimed in claim 13, wherein the first fixing pillar is formed by injecting plastic and encloses the first inner-thread structure.

19. The power supply as claimed in claim 13, wherein the second fixing pillar is formed by injecting plastic and encloses the second inner-thread structure.

20. The power supply as claimed in claim 13, wherein the first fixing pillar, second fixing pillar and force-applying rod together form an U-shape structure.
